(19) United States
(12) Patent Application Publication
(10) Pub. No.: US 2012/0098389 A1
(43) Pub. Date: Apr. 26, 2012

(54) METHOD FOR MOUNTING A PIEZOELECTRIC RESONATOR IN A CASE AND PACKAGED PIEZOELECTRIC RESONATOR

(75) Inventors: Silvio DALLA PIAZZA, St-Imier (CH); Thomas Luethi, Grenchen (CH); Guenter Sallaz, Grenchen (CH); Stephane Borloz, Glutieres (CH)

(73) Assignee: Micro Crystal AG, Grenchen (CH)

(21) Appl. No.: 13/247,279

(22) Filed: Sep. 28, 2011

(30) Foreign Application Priority Data
Oct. 21, 2010 (EP) 10188379.1

(51) Int. Cl. H01L 41/053; B32B 37/00

(52) U.S. Cl. 310/348; 156/73.1

(57) ABSTRACT

The invention concerns a method for mounting a piezoelectric resonator (40) inside a case (80) by ultrasonic bonding of the piezoelectric resonator to a base part of the case. The invention also concerns a small-sized packaged piezoelectric resonator, in which the piezoelectric resonator is ultrasonically bonded inside a base part of the package.

### FIELD OF THE INVENTION

The present invention concerns a method for mounting a piezoelectric resonator inside a case by bonding the piezoelectric resonator to a base part of the case. The present invention also concerns a small-sized packaged piezoelectric resonator, in which the piezoelectric resonator is bonded inside a base part of the package and which is most often used for making frequency generators in particular for portable electronic equipment, in numerous fields such as horology, information technology, telecommunications and the medical field.

### BACKGROUND OF THE INVENTION

Piezoelectric resonators are extensively used as a clock source for electronic circuits in a variety of electronic appliances. As electronic integrated circuits get smaller and smaller, attempts are continuously made to produce smaller and smaller resonators.

In general Surface Mounting Device (SMD) type piezoelectric resonators may include a piezoelectric resonator piece mounted in a package made of an insulating material, such as ceramic. For instance, the packaged resonator can consist in a quartz crystal held at one end, in a cantilever manner, and hermetically sealed inside the package. Annexed FIGS. 1A and 1B show a prior art embodiment of a SMD package in which a tuning fork shaped quartz crystal 2 is enclosed in a package 20. The parallelepipedic package, or case, includes a main part 22, with a rectangular bottom 24 and sides 26, and a cover 28. The surface of the tuning fork shaped quartz crystal resonator is partially covered with a metallization layer forming excitation electrodes as well as upper and lower connection pads 16, 18. The lower connection pads of the resonator 2 are fixed to corresponding electrode terminals 34 of the case by means of conductive adhesive. As shown in FIG. 1B, the electrode terminals can be provided on a step 36 located at one end of the main part 22. The resonator is thus supported in a cantilever manner.

In such prior art devices, the portion of the tuning fork that links the arms of the tuning fork together (referred to hereafter as the linking part) is directly glued to the main part of the case. Therefore, a considerable amount of vibration leakage can occur, leading to detrimentally high crystal impedance. Furthermore, during the process of mounting the resonator inside the package, pressure may cause excess conductive adhesive to leak. As the connection pads 16 and 18 are arranged close together, the excess conductive adhesive can cause short circuits between the excitation electrodes.

The prior art small sized quartz crystal tuning-fork resonator shown in FIG. 2 is supposed to overcome the above mentioned problems. FIG. 2 is more precisely a top view of this so called “three-arm resonator” without its package. The resonator 4 includes a tuning fork shaped part with two parallel arms 12, 14 connected to each other by a linking part 6 and carrying excitation electrodes 8, 10. The excitation electrodes lead to connection pads 30, 32 of the resonator, intended to be electrically connected to the exterior of the package. The resonator 4 also includes a central arm 34 attached to the linking part 6 and extending between the arms 12, 14 of the tuning fork shaped part. The connection pads 30, 32 are arranged on this central arm, and the resonator is intended to be mounted in a parallelepipedic package (not shown) by fixing the central arm 34 to at least one support secured inside the bottom of the package.

In this prior art three-arm resonator, it is the central arm 34 and not the linking 6 that is fixed inside the package or case. Therefore, the tuning fork shaped part is not in direct contact with the case. This feature reduces the amount of vibration leakage and thus also reduces the crystal impedance. Furthermore, prior patent document EP 1 732 219 suggests providing guiding ducts near the connection pads 30, 32 in order to direct any overflow of conductive adhesive away from the opposing electrode, thus preventing short circuits between excitation electrodes.

Three-arm resonators circumvent many difficulties associated with mounting a tuning fork resonator in a case. Nevertheless, the use of conductive adhesive to assemble a resonator and its package remains a problem. Conductive adhesives come in two main categories, epoxy resins and silicon resins. Both categories tend to outgas under vacuum. Resonator packages imperatively have to be vacuum sealed. Otherwise, the stirring of any atmosphere inside the package by the vibrating arms produces drag. For this reason, the atmosphere resulting from the outgasing of the adhesive will adversely affect the operating parameters of the packaged resonator.

Another problem is that most conductive adhesives used in resonators have a glass transition temperature (Tg) that lies between 80° C. and 180° C. Furthermore, these adhesive have to be cured with heat at a temperature above Tg. Therefore, subsequent cooling, starting from above Tg and down to room temperature, always creates thermal stress because of the difference in thermal expansion coefficients between the crystal chip and the ceramic package. This stress induces a considerable amount of strain in the resonator. Sometimes the stress causes the resonator to move out of position, thus relaxing the strain induced in the quartz crystal. More often, the strain in the quartz crystal does not relax and becomes permanent. One known way of avoiding that the strain affects the operating parameters of the resonator is to design a resonator having a decoupling zone intercalated between the connection pads of the resonator and the vibrating arms. However, such an arrangement has the disadvantage of increasing the size of the resonator. Another know way of avoiding the presence of stress and strain, is to use a conductive adhesive with a lower Tg. However, such adhesives are soft and have a tendency to let the resonator move out of position in case of shock.

Instead of using a conductive adhesive in order to glue the quartz crystal resonator onto a support provided inside the main part of the case, it is also known to hard-solder the quartz crystal resonator onto the support. Contrarily to glue, solder turns to liquid when subjected to a temperature above its melting point. It is therefore necessary to use solder or brazant with a melting point higher than the highest temperature the packaged resonator is expected to experience during its service life. In the case of a SMD type packaged resonator, this highest temperature will be about 260° C., which corresponds to the temperature of the reflow soldering oven that is used to bond the SMD resonator to a circuit board. It is therefore easy to understand that at least part of the resonator and of the case will be heated to a temperature above 260° C. during the process of hard-soldering. Subsequent cooling the resonator down to room temperature, will submit the quartz crystal to an enormous amount of mechanical stress. Furthermore, solder can also outgas under vacuum.

It is further known to mount a quartz crystal resonator inside a case by thermocompression bonding. Thermocompression bonding uses contacts made of ductile materials, usually stud bumps created from gold or copper wire. These bumps are located on the electrode terminals of the case. On the opposite side, the connection pads of the quartz crystal resonator are preferably made, or coated, with the same metal. To create a bond, the resonator and the case are first heated to above 300° C., and the connection pads of the resonator are then pressed down for several tens of seconds onto the stud bumps with a defined bonding force. The joint builds up by diffusion welding. One advantage of this last method is that there is no outgasing. However, as in the previous method, cooling from above 300° C. to room temperature creates a very large amount of thermal stress. Furthermore, the mechanical force that has to exerted on the quartz crystal sometimes causes the resonator to break. Finally, thermocompression bonding is a very time consuming process, its most significant advantage compared to other known methods is probably the possibility to position the resonator inside the case with great accuracy.

### SUMMARY OF THE INVENTION

It is therefore an object of the present invention to allow mounting a piezoelectric resonator in a case in practically no time, while at the same time ensuring that the resonator is positioned in the case with excellent accuracy. Indeed, as the dimensions of packaged piezoelectric resonators become smaller and smaller, accurate positioning of the resonator inside the case becomes more and more critical.

It is another object of the present invention to provide for joining the piezoelectric resonator and the case without any significant outgasing. Indeed, as the dimensions of packaged piezoelectric resonators become smaller and smaller, the space in which the outgas can accumulate also becomes smaller and smaller. Therefore, the atmosphere created by outgasing tends to be denser in a packaged resonator of such small dimensions. In other words, the problem of outgasing becomes more and more critical as packaged piezoelectric resonators become smaller.

It is still a further object of the present invention to provide for bonding the piezoelectric resonator in the case without inducing significant thermal stress. Indeed, if the amount of thermal stress can be reduced, the size of the decoupling zone between the connection pads and the vibrating arms of the resonator can also be reduced in size. By reducing the size of the decoupling zone, it is possible to make packaged piezoelectric resonators with smaller overall dimensions; thus bringing miniaturization one step further.

To these ends, a first aspect of the present invention concerns a method for mounting a piezoelectric resonator inside a case by bonding the piezoelectric resonator to a base part of the case, the piezoelectric resonator having a lower surface carrying first and second connection pads and the base part having an upper surface carrying first and second electrode terminals, the method comprising:
positioning the piezoelectric resonator above the electrode terminals, the electrode terminals being provided with first and second stud bumps, and the connection pads being oriented toward the stud bumps;
lowering the piezoelectric resonator onto the base part so that the connection pads align with the stud bumps on the electrode terminals;
applying a bias force to the upper side of the piezoelectric resonator; and
applying ultrasonic energy in the form of oscillations, the ultrasonic energy being isothermally transferred across the piezoelectric resonator to the base part for creating a diffusion bond between the connection pads and the stud bumps so as to provide electrical connection of the piezoelectric resonator with the electrode terminals.
   Furthermore, a second aspect of the present invention concerns a packaged piezoelectric resonator comprising:
a case including a main part and a cover fixed to said main part closing the case, the main part having an electrode terminal portion on the inside surface thereof;
a piezoelectric resonator arranged inside the case;
   wherein a lower surface of the piezoelectric resonator is ultrasonically bonded to electrode terminals of the electrode terminal portion so as to both attach the piezoelectric resonator to the inside surface of the main part (80) and provide electrical connection of the piezoelectric resonator with the electrode terminals.

### BRIEF DESCRIPTION OF THE DRAWINGS

Other features and advantages of the present invention will appear upon reading the following description, given solely by way of non-limiting example, and made with reference to the annexed drawings, in which:

FIG. 1A shows a prior art piezoelectric tuning fork resonator;

FIG. 1B shows a prior art packaged piezoelectric resonator comprising the tuning fork resonator of FIG. 1A and a case;

FIG. 2 shows prior art “three-arm” tuning fork resonator;

FIG. 3 shows an exemplary embodiment of a piezoelectric resonator intended to be assembled with a case (not shown) in order to provide a packaged piezoelectric resonator according to the invention;

FIG. 4 is a top view of a package, or case, adapted to house the quartz crystal tuning-fork resonator shown in FIG. 3;

FIG. 5 shows the case of FIG. 4 with the resonator of FIG. 3 mounted inside;

FIG. 6 schematically illustrates the method of mounting a piezoelectric resonator inside a case by ultrasonically bonding the piezoelectric resonator to electrode terminals on the bottom of the case.

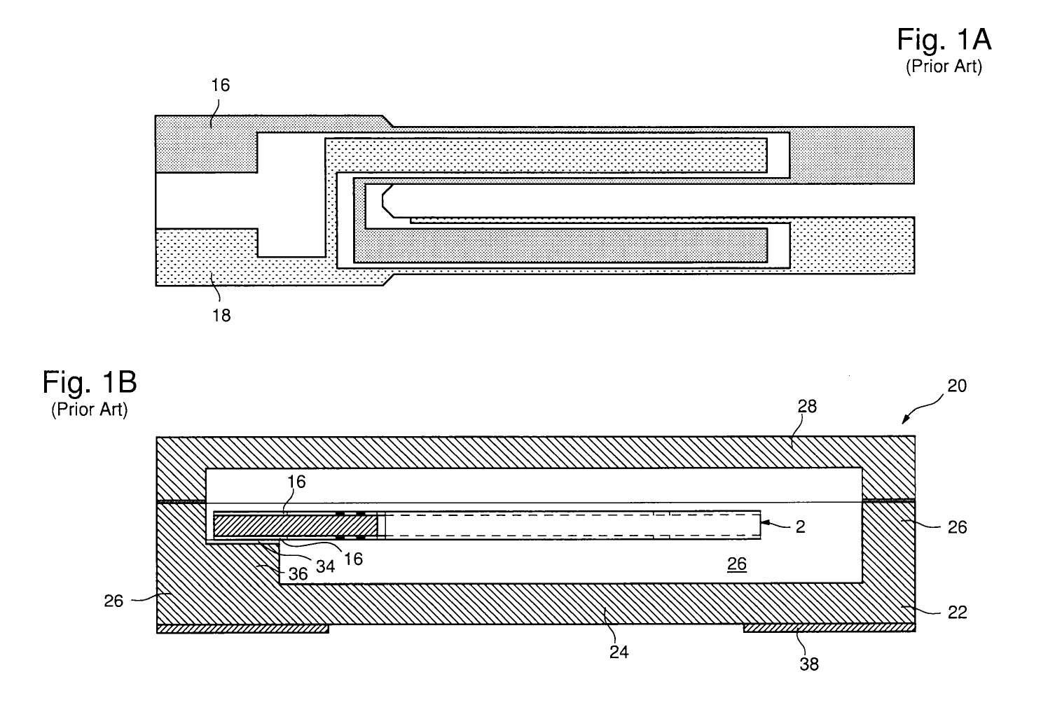

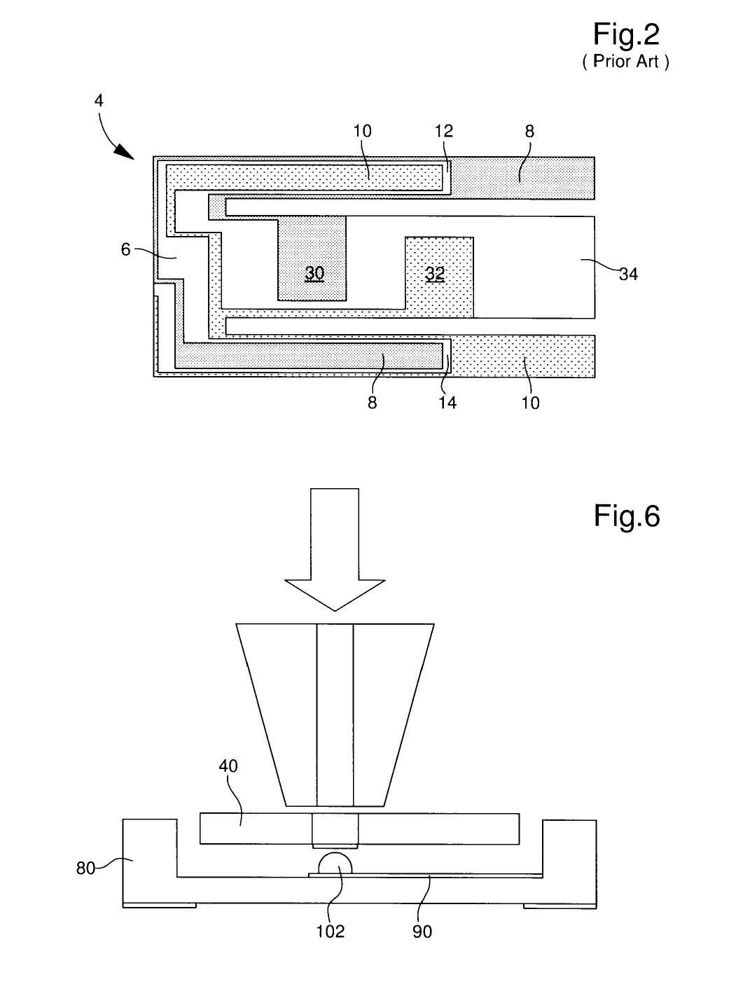

### DETAILED DESCRIPTION OF THE INVENTION

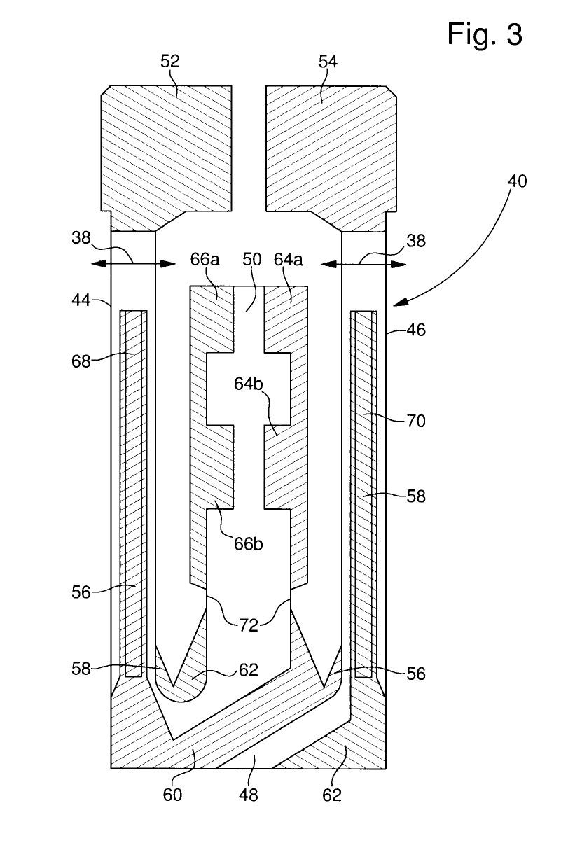

FIG. 3 shows a first embodiment of a piezoelectric resonator intended to be assembled with a case (not shown) in order to provide a packaged piezoelectric resonator according to the invention. The resonator designated by the reference numeral 40, includes a tuning fork shaped part with two vibrating arms 44 and 46 joined by a linking part 48 to which a central arm 50, located between arms 44 and 46 and parallel thereto, is attached. The whole resonator is in a single piece, preferably made from quartz. The vibrating arms 44 and 46 carry two groups of electrodes 56, 58. The electrodes in one group are connected to each other by conductive paths, respectively 60 and 62, carried by linking part 48. As they are shown in the drawing, the electrodes and conductive paths are arranged so as to make arms 44 and 46 vibrate in flexure mode as indicated by double arrows 38. However, they could have a different configuration to make the arms vibrate in the same mode or another mode (torsion, shear, etc.).

Returning to central arm 50, FIG. 3 shows that it carries four conductive connection pads 64a, 64b and 66a, 66b on its upper surface (or back face). As can be seen, one pair of the connection pads is arranged on each side of the central arm. Furthermore, the two pads in one pair are located on either side of the centre of gravity G (not shown) of the resonator lengthways. One pair of connection pads 64a, 64b is connected by means of a conductive path 60 to the first group of electrodes 56 and the other pair of connection pads 66a, 66b is connected in a similar way to the second group of electrodes 58. The central arm 50 also carries four additional connection pads (not visible in FIG. 3) on its lower surface (or front face). The arrangement of the connection pads on the lower surface of the central arm is identical to the arrangement of the connection pads on the upper surface. In other words, each connection pad on one surface is located directly across from a connection pad on the other surface. An advantage of this arrangement is that the piezoelectric resonator 40 can be mounted on one or the other of its faces without any need to adapt the connection arrangement. As will be explained more in detail later on, the connection pads carried on the lower surface of the central arm are used for fixing the resonator inside its packaging (not shown), as well as for connecting electrodes 56, 58 to the outside.

As shown in FIG. 3, the width of the central arm 50 is preferably at least slightly more than twice the width of an arm 44 or 46 of the tuning fork shaped part. The length of the central arm 50 is preferably shorter than the length of the arms 44, 46, as shown by FIG. 3. One can further observe that the central arm 50 is substantially equidistant from arms 44 and 46. The distance separating the central arm from either of arms 44 and 46 is roughly equal to that which separates the two arms of a conventional tuning fork resonator. Furthermore, it is important that the central arm 50 has a greater mass than that of arms 44 and 46 which have to vibrate.

In order to produce an electric field which is both more homogeneous and more intense, at least one groove 68, 70 is formed in each main surface of the vibrating arms, or at least in one (upper or lower) main surface of each vibrating arm. The grooves allow to reduce energy consumption, as well as to keep vibration losses in the arms low even when the size of the vibrating piece is miniaturized. In order to further increase the vibrating coupling effect of the vibrating arms, it is possible to have grooves 68, 70 extend into the linking part 48. Indeed, portions of the grooves that extend into the linking part 48, where mechanical stresses are the strongest, allow retrieving the electrical field in this highly stressed.

FIG. 3 further shows that each vibrating arm (44, respectively 46) ends in a flipper (52, respectively 54) which extends beyond the central arm 50. In the depicted embodiment, the flipper is more than twice as wide as the rest of the vibrating arm. In order to reduce the overall width of the resonator, the rectangular shaped flippers 52, 54 are preferably not arranged symmetrically with respect to the longitudinal axis of the vibrating arms. Rather, as shown in FIG. 3, the flippers can be offset towards the centre axis of the resonator, giving each vibrating arm a shape reminiscent of a hammer. It will be appreciated that adding flippers increases the inertia of the vibrating arms, so that the vibrating arms behave like if they were considerably longer. Therefore, using flippers allows reducing the length of the resonator.

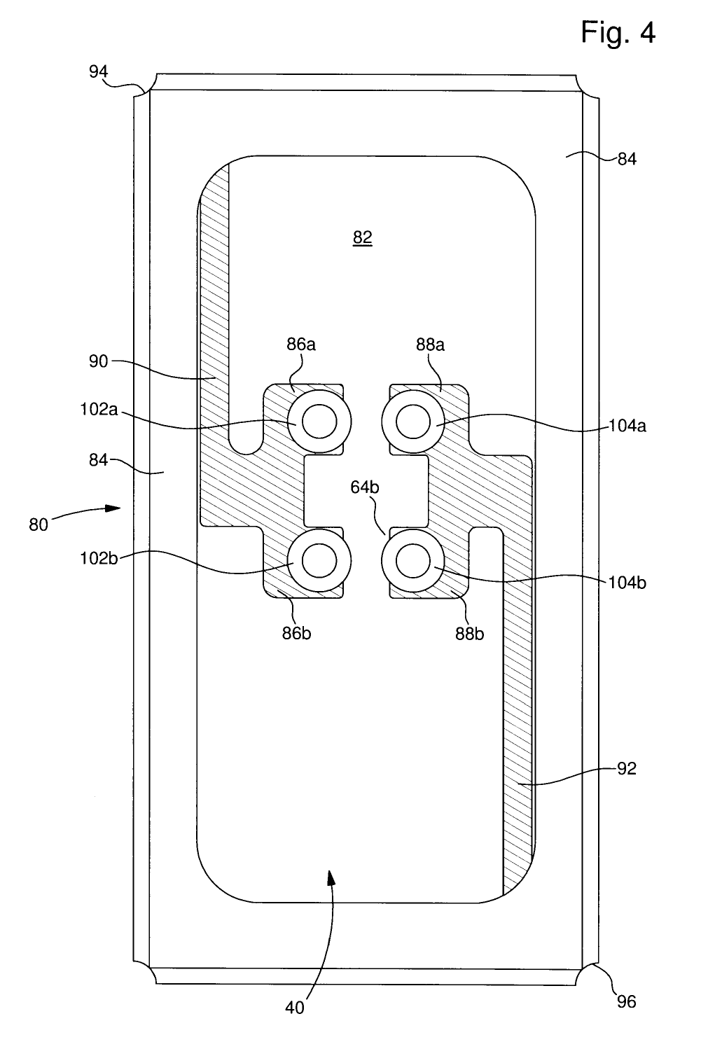

FIG. 3 finally shows that decoupling means, in the form of V-shaped notches 72, are present at the base of the central arm 50, between the connection pads 64, 66 and the linking part 48. These notches contribute to mechanically decouple the central arm 50 from the vibrating arms 44 and 46. FIG. 4 is a top view of a package, or case, adapted to house the quartz crystal tuning-fork resonator shown in FIG. 3. The rectangular-shaped package is of the surface-mount type and is made up of a main part 80 and a cover (not shown). The main part of the case includes a bottom 82 and sides 84 forming a cavity in which the resonator 40 shall be mounted. The cover is welded to the main part for hermetically closing the case. The cover is preferably ceramic like the rest of the case. However, it is well known that covers made of metal, or of glass, can also be used for closing ceramic cases. The main part 80 of the case is made up of superposed layers of ceramic, including at least a first ceramic layer and a second ceramic layer. The ceramic layers are flat and have the same substantially rectangular outer shape. The first layer forms the bottom 82 of the case, while the second layer is provided with a substantially rectangular opening intended to form the cavity for receiving the resonator. The rectangular opening is surrounded by the sides 84.

Electrode terminals 86a, 86b, 88a, 88b are formed on the bottom 82 of the cavity, for electric connection with the three-arm resonator 40 (FIG. 3). A pair of mounting electrodes (not shown) is formed on the bottom outer surface of the case for mounting the packaged resonator on a printed circuit board. The mounting electrodes are arranged near opposite ends of the rectangular first ceramic layer. They are connected electrically to the upper surface of the first ceramic layer by two corner metallizations that bridge the edges of the first ceramic layer near two opposite corners 94, 96 of the rectangular piece. The two corner metallizations (not shown) are formed by conductive film. Conductive paths (referenced 90 and 92 respectively) are formed on the laminated upper surface 82 of the first ceramic layer and connect each of the corner metallizations to a pair of electrode terminals (86a, 86b or 88a, 88b). The conductive paths 90, 92 extend from the electrode terminals, through the sides 84 of the case, all the way to corners 94 and 96 of the first ceramic layer. A portion of each conductive path is therefore sandwiched between first and second superposed ceramic layers.

Referring again to FIG. 4, one can see that a stud bump, or hemispherical protrusion 102a, 102b, 104a, 104b, is formed on each of the electrode terminals 86a, 86b or 88a, 88b. These stud bumps are preferably silver, gold, aluminium or copper, or a combination of these. According to the present invention, the stud bumps are more preferably gold. The stud bumps can be grown on the electrode terminals by utilizing well-known masking and plating techniques, or by using sputtering. However, according to a preferred implementation of the present invention, the stud bumps are bonded to the electrode terminals by the technique known as “ball bumping”. An advantage of ball bumping is that it can be done automatically using commercially available automatic wire bonders. If the stud bumps are gold, the electrode terminals should preferably also be gold. The thickness of the gold layer on the surface of the electrode terminals can be around 1.2 microns, preferably between 0.5 and 2 microns.

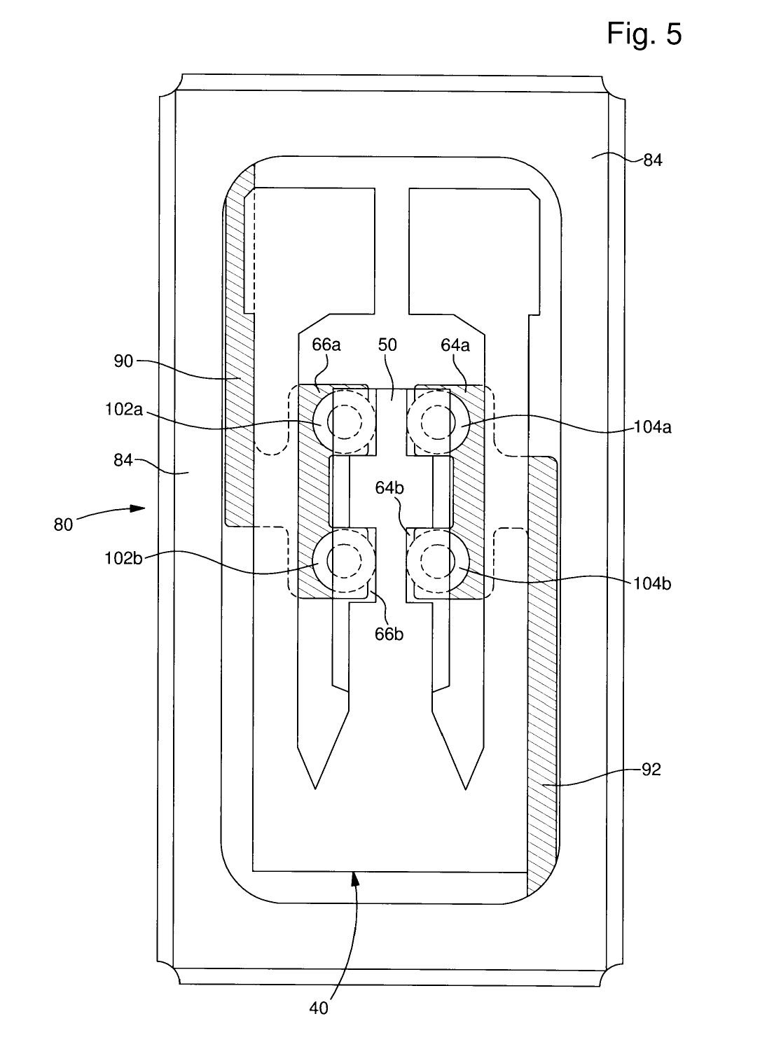

FIG. 5 shows the main part 80 of the case of FIG. 4 with the resonator 40 of FIG. 3 mounted inside. As can be observed in the drawing, the connection pads carried on the lower surface of the central arm 50 are bonded to the stud bumps 102a, 102b, 104a, 104b previously formed on the bottom 82 of the case. One will understand that the stud bumps are used for fixing the resonator inside its case, as well as for connecting electrodes 56, 58 to the outside. As can further be seen in FIG. 5, the stud bumps are positioned directly below the connection pads 64a, 64b, 66a, 66b on the upper surface of the central arm 50 of the resonator. This feature allows optically aligning the resonator 40 and the main part 80 of the case before bonding the resonator to the stud bumps.

FIG. 6 schematically illustrates the method of mounting a piezoelectric resonator inside a case by ultrasonically bonding the piezoelectric resonator to electrode terminals on the bottom of the case. Indeed, according to the present invention, the piezoelectric resonator element of a packaged piezoelectric resonator is bonded inside a base part of the package by ultrasonic bonding. As can be seen in FIG. 6, it is the electrode terminals on the bottom side of the resonator 40 that are bonded to the stud bumps 102. This configuration corresponds to what is commonly known as flip-chip bonding. The main steps of the method of ultrasonic flip-chip bonding are, first, pressing the electrode terminals of the quartz crystal resonator against the stud bumps 102 and then to submit the stud bumps and the electrode terminals together to ultrasonic oscillations. The joint builds up by diffusion welding without requiring the application of heat. Ultrasonic flip-chip bonding has many advantages when applied to bonding a resonator inside a ceramic package. To begin with, there is no outgasing and the ultrasonic bonding can be implemented at room temperature. Therefore, there is no significant thermal stress. Furthermore, thanks to the presence ultrasonic vibrations, the mechanical force that must be exerted on the quartz crystal in order to press it against the stud bumps can be relatively weak. This reduces the risk of breaking the resonator. Using ultrasonic vibrations also considerably speeds up the process of diffusion welding. This feature of the present invention makes the bonding method much faster. Finally the flip-chip configuration used in ultrasonic flip-chip bonding allows to position the connection pads 64a, 64b, 66a, 66b (FIG. 5) on the upper surface of the resonator relative to the stud bumps with great precision (better than +/−30 microns.

In the case where the stud bumps are gold, the metallizations forming the connection pads of the resonator are preferably also gold. The thickness of these gold layers can be as small as 0.2 microns. The advantage of using only a very thin layer of gold for the connection pads is that the connection pads can be formed during the same process step, during which the excitation electrodes of the tuning-fork resonator are formed.

What is claimed is:

1. A packaged piezoelectric resonator comprising:
a case including a main part (80) and a cover fixed to said main part closing the case, the main part having an electrode terminal portion on the inside surface thereof;
a piezoelectric resonator (40) arranged inside the case;
characterized in that a lower surface of the piezoelectric resonator (40) is ultrasonically bonded to electrode terminals (86a, 86b, 88a, 88b) of the electrode terminal portion so as to both attach the piezoelectric resonator to the inside surface of the main part (80) and provide electrical connection of the piezoelectric resonator with the electrode terminals.

2. The packaged piezoelectric resonator of claim 1, wherein the piezoelectric resonator comprises a planar tuning-fork-shaped part with two parallel vibrating arms (44, 46) connected to each other by a linking part (48).

3. A method for mounting a piezoelectric resonator inside a case by bonding the piezoelectric resonator to a base part of the case, the piezoelectric resonator having a lower surface carrying first and second connection pads and the base part having an upper surface carrying first and second electrode terminals, the method comprising:
positioning the piezoelectric resonator above the electrode terminals, the electrode terminals being provided with first and second stud bumps, and the connection pads being oriented toward the stud bumps;
lowering the piezoelectric resonator onto the base part so that the connection pads align with the stud bumps on the electrode terminals;
applying a bias force to the upper side of the piezoelectric resonator; and
applying ultrasonic energy in the form of oscillations, the ultrasonic energy being isothermally transferred across the piezoelectric resonator to the base part for creating a diffusion bond between the connection pads and the stud bumps so as to provide electrical connection of the piezoelectric resonator with the electrode terminals.

4. The method of claim 3, wherein the piezoelectric resonator comprises a planar tuning-fork-shaped part with two parallel vibrating arms connected to each other by a linking part.

5. The method of claim 4, wherein the piezoelectric resonator comprises a central arm extending from the linking part parallel to the vibrating arms, between and substantially at equal distance from the vibrating arms, and wherein the lower surface of the central arm carries the first and second connection pads.

6. The method of claim 5, wherein the first connection pad is a first lower connection pad arranged on a right side of the lower surface of the central arm, wherein the second connection pad is a second lower connection pad arranged on a left side of the lower surface of the central arm, and wherein the upper surface of the central arm carries first and second upper connection pads located opposite the lower connection pads.

7. The method of claim 6, wherein the distance between centres of the first and second stud bumps is slightly more than the distance between centres of the first and second connection pads, and wherein the positioning step includes optically aligning the piezoelectric resonator and the base part so that the first and second upper connection pads are indexed with corresponding stud bumps on the base part before the lowering and force application steps.

8. A packaged piezoelectric resonator comprising:
a case including a base part and a cover fixed to said base part closing the case, the base part having an electrode terminal portion on the inside thereof;
a piezoelectric resonator arranged inside the case, a lower surface of the piezoelectric resonator carrying a first and a second connection pad;
characterised in that the piezoelectric resonator is bonded to the base part by means of the method according to any one of claims 3 to 7.
